(19) United States
(12) Patent Application Publication
(10) Pub. No.: US 2026/0214837 A1
(43) Pub. Date: Jul. 23, 2026

(54) FAN AND ELECTRONIC DEVICE

(71) Applicants: CHAMP TECH OPTICAL (FOSHAN) CORPORATION, Foshan (CN); Foxconn Technology Co., Ltd., New Taipei (TW)

(72) Inventors: XIAO-GUANG MA, Foshan (CN); ZHENG LUO, Foshan (CN); YUNG-PING LIN, New Taipei (TW)

(21) Appl. No.: 19/176,539

(22) Filed: Apr. 11, 2025

(30) Foreign Application Priority Data
Jan. 22, 2025 (CN) 202510108231.2

(51) Int. Cl. H05K 7/20

(52) U.S. Cl. CPC H05K 7/20172

(57) ABSTRACT

A fan includes a frame including a mounting area, wires, a terminal board, and a limiting assembly. A first limiting member, a first mounting plate, and a second mounting plate are provided in the mounting area. The first limiting member includes a first limiting hole, the first mounting plate and the second mounting plate includes mounting grooves. The terminal board is movably inserted into the mounting grooves and comprises a second limiting hole and a plurality of wiring holes, an axis of the first limiting hole coincides with an axis of the second limiting hole, and the wiring holes connect the wires. The limiting assembly connects the first limiting hole and the second limiting hole, and a diameter of the second limiting hole is greater than a diameter of at least part of the limiting assembly. The present disclosure further provides an electronic device.

### FIELD

The subject matter relates to heat dissipation, and in particular to a fan and an electronic device.

### BACKGROUND

With rapid development of electronic technology, heat generated by electronic components generate needs to be dissipated immediately. Fans are widely used to help dissipating heat of the electronic components. A typical fan usually includes a frame, internal components housed in the frame, and conductive wires connecting the internal components with external circuits. In assembling the fan, the conductive wires are mounted on a backet which is mounted on the frame, and then the conductive wires are clamped through fixing members. However, the bracket and the fixing members occupy a large space, which reduces a heat dissipation space of the electronic device. In addition, the bracket and the fixing members increase the manufacture cost of the fan.

### BRIEF DESCRIPTION OF THE DRAWINGS

Implementations of the present technology will now be described, by way of example only, with reference to the attached figures.

FIG. 1 is a diagrammatic view illustrating a fan according to a first embodiment of the present disclosure.

FIG. 2 is an exploded view of the fan shown in FIG. 1.

FIG. 3 is a diagrammatic view illustrating a frame of the fan shown in FIG. 1.

FIG. 4 is a diagrammatic view illustrating a terminal board of the fan shown in FIG. 1.

FIG. 5 is an exploded view of a limiting assembly of the fan shown in FIG. 1.

FIG. 6 is a diagrammatic view illustrating a fan according to a second embodiment of the present disclosure.

FIG. 7 is an exploded view of the fan shown in FIG. 6.

FIG. 8 is a diagrammatic view illustrating a frame of the fan shown in FIG. 6.

FIG. 9 is a diagrammatic view illustrating a terminal board of the fan shown in FIG. 6.

FIG. 10 is an exploded view of a limiting assembly of the fan shown in FIG. 6.

FIG. 11 is a diagrammatic view illustrating a fan according to a third embodiment of the present disclosure.

FIG. 12 is an exploded view of the fan shown in FIG. 11.

FIG. 13 is a diagrammatic view illustrating a frame of the fan shown in FIG. 11.

FIG. 14 is a diagrammatic view illustrating a terminal board of the fan shown in FIG. 11.

FIG. 15 is an exploded view of a limiting assembly of the fan shown in FIG. 11.

FIG. 16 is a diagrammatic view illustrating a fan according to a fourth embodiment of the present disclosure.

FIG. 17 is a diagrammatic view illustrating the fan according to the fourth embodiment of the present disclosure.

FIG. 18 is a diagrammatic view illustrating the fan according to the fourth embodiment of the present disclosure.

FIG. 19 is a diagrammatic view illustrating a fan according to a fifth embodiment of the present disclosure.

FIG. 20 is a block diagram illustrating an electronic device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

### First embodiment

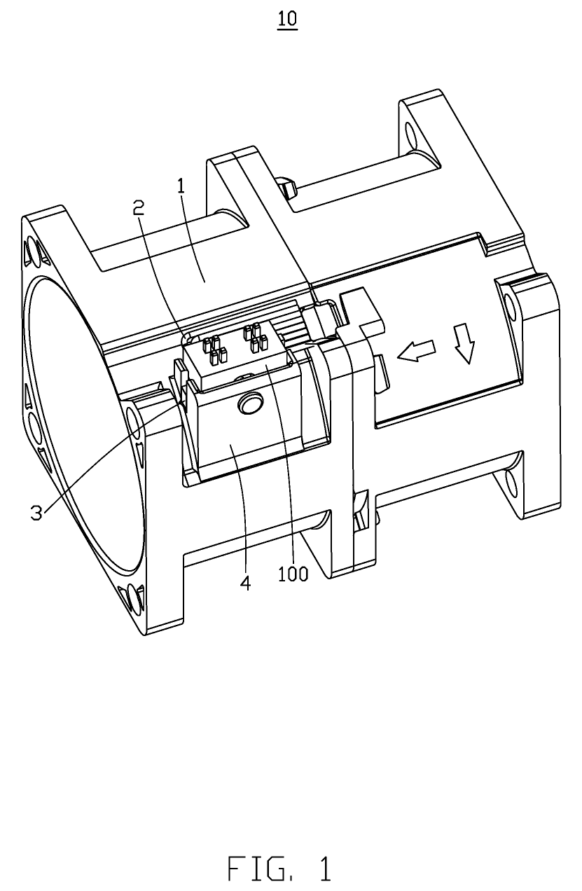

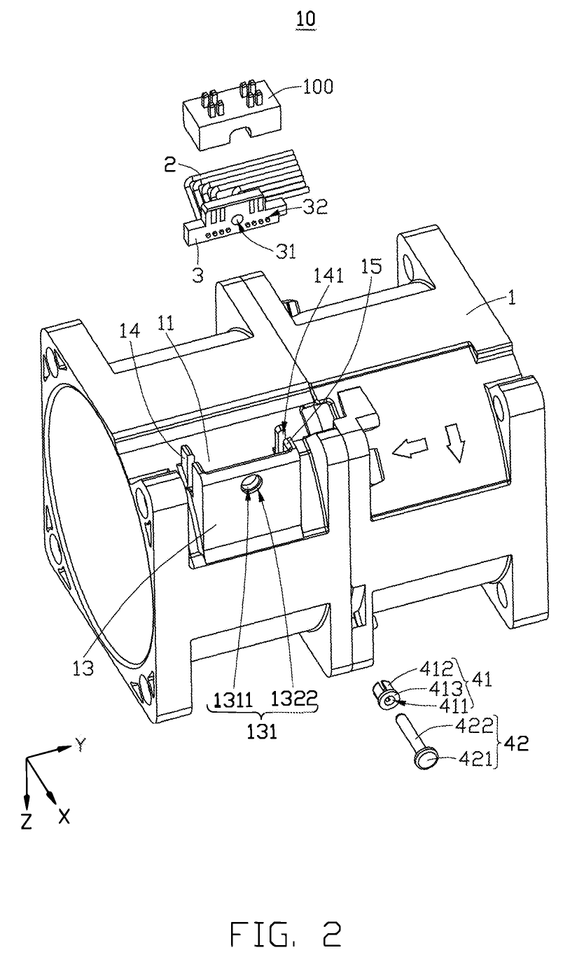

Referring to FIGS. 1 to 5 , an embodiment of the present disclosure provides a fan 10. The fan 10 includes a frame 1, a plurality of wires 2, a terminal board 3, and a limiting assembly 4. A first end of the wire 2 extends into the frame 1, and a second end of the wire 2 opposite to the first end extends outside the frame 1. The frame 1 includes a mounting area 11, and the mounting area 11 is provided with a first limiting member 13, a first mounting plate 14 and a second mounting plate 15. The first mounting plate 14 and the second mounting plate 15 are arranged opposite to each other along a second direction Y, and the first mounting plate 14 and the second mounting plate 15 are respectively located on both sides of the first limiting member 13 along the second direction Y. The first limiting member 13 is provided with a first limiting hole 131 penetrating the first limiting member 13 along a first direction X, the first mounting plate 14 is provided with a mounting groove 141 penetrating the first mounting plate 14 along the second direction Y, and the second mounting plate 15 is provided with another mounting groove 141 penetrating the second mounting plate 15 along the second direction Y. The terminal board 3 is movably inserted into the mounting grooves 141. The terminal board 3 is provided with a second limiting hole 31 and a plurality of wiring holes 32 which penetrate the terminal board 3 along a thickness direction of the terminal board 3. An axis of the first limiting hole 131 extending along the first direction X coincides with an axis of the second limiting hole 31 extending along the first direction X. The wiring hole 32 is configured to connect to the second end of the wire 2. The limiting assembly 4 is configured to connect the first limiting hole 131 and the second limiting hole 31, and an inner diameter of the second limiting hole 31 is larger than a diameter of at least part of the limiting assembly 4, so that the terminal board 3 is floatingly connected to the mounting groove 141.

The terminal board 3 of the fan 10 is provided with a wiring hole 32, and the wire 2 can extend through the wiring hole 32 to connect with the terminal board 3. The mounting area 11 of the frame 1 is provided with a mounting groove 141, and the terminal board 3 can be movably inserted into the mounting groove 141, so that the wire 2 and the terminal board 3 are located in the same area on the frame 1. And then the first limiting hole 131 and the second limiting hole 31 are connected by the limiting assembly 4, so that the terminal board 3 can be limited in the mounting groove 141. The inner diameter of the second limiting hole 31 is larger than the diameter of at least part of the limiting assembly 4, which can realize the floating assembly of the terminal board 3 in the mounting groove 141, and reduce the influence of vibration on the connection stability between a connector 100 and the terminal board 3. The arrangement of the wiring hole 32 allows the fixing and mounting of the wire 2 without the use of additional components, reduces the difficulty of assembling the fan 10, and can also ensure the heat dissipation space inside the electronic device 200, improve the heat exchange efficiency, and reduce the computing load of the heat dissipation system.

Some embodiments of the present disclosure will be described in detail with reference to the drawings. If no conflict, the following embodiments and features in the embodiments can be combined with each other.

In the following, for the convenience of description, the first direction X is defined as the X-axis direction, the second direction Y is defined as the Y-axis direction, a third direction Z is defined as the Z-axis direction, and the first direction X, the second direction Y and the third direction Z are perpendicular to each other.

In some embodiments, the frame 1 is an outer shell of the fan 10, and can provide a stable mounting structure for other components of the fan 10 to ensure that the components can operate safely. The frame 1 can also protect internal components of the fan 10 from external factors, such as dust, humidity or other physical damage. The frame 1 used in the present disclosure is made of plastic or metal, which can be selected according to actual needs and is not limited here.

The mounting area 11 is any area on the frame 1. For example, the mounting area 11 can be an area of an end of the frame 1, or an area on a side of the frame 1. It can be selected according to the arrangement of the fan 10 inside the electronic device, as long as it is convenient to connect with the connector 100, and no limitation is made here.

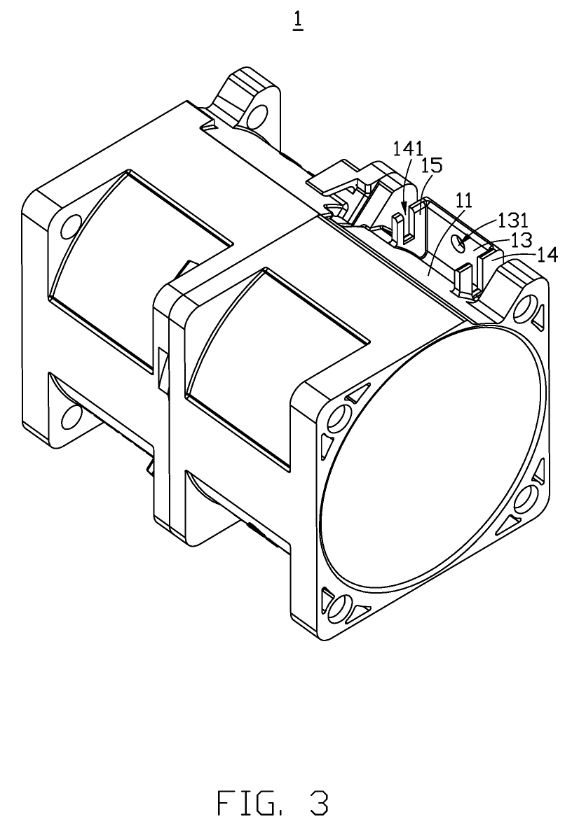

Please continue to refer to FIG. 3, the mounting area 11 is provided with the first limiting member 13, the first mounting plate 14 and the second mounting plate 15. The first mounting plate 14 and the second mounting plate 15 are arranged opposite to each other along the second direction Y. The first limiting member 13 is provided with the first limiting hole 131 that penetrates the first limiting member 13 along the first direction X, the first mounting plate 14 is provided with one mounting groove 141 penetrating the first mounting plate 14 along the second direction Y, and the second mounting plate 15 is provided with one mounting groove 141 penetrating the second mounting plate 15 along the second direction Y. When viewed along the first direction X, the first mounting plate 14 and the second mounting plate 15 are located on both sides of the first limiting member 13. It can be understood that the axis of the first limiting hole 131 extends along the first direction X, and the mounting grooves 141 defined on the first mounting plate 14 and the second mounting plate 15 are located on the same straight line along the second direction Y, that is, the axis of the first limiting hole 131 extending along the first direction X is perpendicular to a through direction of the mounting groove 141.

It should be noted that a depth and a width of the mounting groove 141 are not limited in the present disclosure, and the depth and width can be selected according to a size of the terminal board 3.

In the present disclosure, the first limiting member 13, the first mounting plate 14, the second mounting plate 15 and the frame 1 may be formed separately or as an integral unit. The first limiting member 13, the first mounting plate 14, the second mounting plate 15 and the frame 1 which are formed separately are connected by bonding, welding, or detachable connecting means. It can be understood that when the components on the mounting area 11 and the frame 1 are formed as an integral unit or connected by bonding or welding, the overall strength of the frame 1 is high and the service life of the frame 1 is longer. When the components on the mounting area 11 and the frame 1 are connected by detachable means, for example, the components on the mounting area 11 are latched to the frame 1, the component can be replaced individually when it is damaged, thereby reducing the maintenance cost of the fan 10.

In one embodiment, the first limiting member 13, the first mounting plate 14, the second mounting plate 15 and the frame 1 are formed as an integral unit. It can be understood that when the components on the mounting area 11 and the frame 1 are an integrally molded structure, no additional fixing components are required to fix the first limiting member 13, the first mounting plate 14 and the second mounting plate 15 to the frame 1. Therefore, a space occupied by the first limiting member 13, the first mounting plate 14 and the second mounting plate 15 becomes smaller, and the fixing and installation of the wire 2 and the terminal board 3 do not require the use of additional fixing components, thereby ensuring the heat dissipation space inside the electronic device, improving the heat exchange efficiency, and reducing the computing load of the heat dissipation system. In addition, the frame 1 has higher strength and a longer service life.

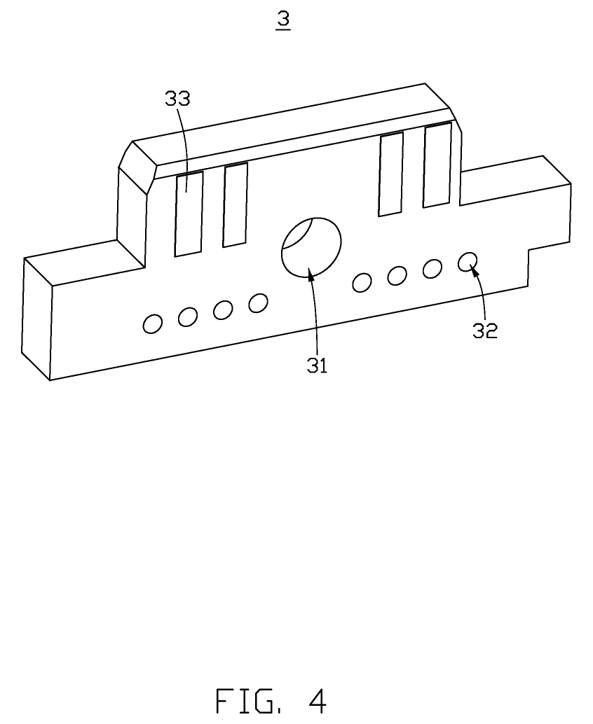

In some embodiments, the terminal board 3 is used to connect the fan 10 to a power source or a control system, and provides an electrical interface for the connector 100, so that the fan 10 can receive power and work. Specifically, please continue to refer to FIG. 4, the terminal board 3 is provided with a plurality of electrical contact areas 33, and the electrical contact areas 33 are distributed on two surfaces of the terminal board 3, and at least some of the electrical contact areas 33 have different areas. It can be understood that the electrical contact area 33 is used for electrical connection with the connector 100. The electrical contact areas 33 are distributed on both sides of the terminal board 3 and have different areas, which can provide more contact surfaces and help ensure a more stable electrical connection. In a vibration environment, the large contact area can reduce the risk of circuit breaking due to poor contact and improve the reliability and durability of the fan 10.

The terminal board 3 is inserted into the mounting grooves 141 of the first mounting plate 14 and the second mounting plate 15. A thickness of a portion of the terminal board 3 being in contact with the mounting groove 141 is less than a width of the mounting groove 141, that is, the terminal board 3 is movable within the mounting groove 141 in the first direction X. It can be understood that in an actual installation process, due to manufacturing tolerances, assembly errors and other reasons, there are alignment problems when the terminal board 3 is inserted into the connector 100. The terminal board 3 is movable within the mounting groove 141 in the first direction X, which facilitates insertion of terminal board 3 into the connector 100, thereby simplifying the installation process and reducing the stress concentration caused by forced alignment. The present disclosure does not limit a thickness difference between the mounting groove 141 and the terminal board 3, and the thickness difference can be selected according to the specific application scenario and specifications of the fan 10.

The terminal board 3 movably inserted into the mounting grooves 141 is provided with a second limiting hole 31 which passes through the terminal board 3 in the thickness direction. When the terminal board 3 is installed in the mounting grooves 141, an axis of the second limiting hole 31 along the first direction coincides with an axis of the first limiting hole 131 of the first limiting member 13 along the first direction X. By connecting the first limiting hole 131 and the second limiting hole 31 through the limiting assembly 4, the terminal board 3 can be floatingly connected to the mounting grooves 141.

In the embodiment of the present disclosure, floatingly connected means that when the terminal board 3 is installed in the mounting grooves 141, a size of the mounting groove 141 is larger than a size of an installation part of the terminal board 3, and there is a gap between the terminal board 3 and the mounting groove 141, so that the terminal board 3 can move slightly in one or more directions. It can be understood that floating assembly can eliminate certain installation errors, ensure the correct insertion of the terminal board 3 into the connector 100. Floating assembly also plays a role of shock absorption and damping to a certain extent, reducing the influence of the mechanical vibration of the frame during the rotation of the fan 10 on the connection stability of the terminal board 3 and the connector 100.

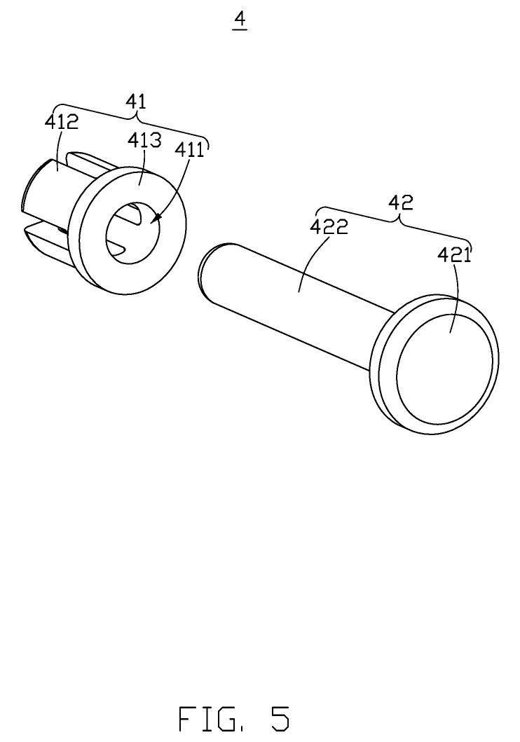

Please continue to refer to FIG. 5, the limiting assembly 4 includes an expansion member 41 and a first positioning pin 42. The expansion member 41 is inserted into the first limiting hole 131. The first limiting hole 131 includes a first hole section 1311 and a second hole section 1322. The second hole section 1322 is arranged at one end of the first hole section 1311 facing away from the mounting area 11, and a diameter of the second hole section 1322 is larger than a diameter of the first hole section 1311. The expansion member 41 includes an expansion body 412 and a second limiting portion 413, a diameter of the second limiting portion 413 is greater than an inner diameter of the first hole section 1311, the expansion body 412 is inserted into the first hole section 1311, the second limiting portion 413 is received in the second hole section 1322, and the second limiting portion 413 does not protrude from a surface of the first limiting member 13. It can be understood that the second limiting portion 413 does not protrude from the surface of the first limiting member 13, which improves the aesthetics and reduces the collision of other components in the fan with the limiting assembly 4, thereby ensuring the stable installation of the limiting assembly 4.

The expansion member 41 is provided with an expansion hole 411. When the expansion member 41 is embedded in the first limiting hole 131, an axis of the second limiting hole 31 along the first direction X coincides with an axis of the expansion hole 411 along the first direction X. The first positioning pin 42 includes a first limiting portion 421 and a pin body 422 connected to each other. A diameter of the pin body 422 is smaller than a diameter of the second limiting hole 31. The pin body 422 is inserted into the expansion hole 411 and the second limiting hole 31. The first limiting portion 421 abuts against a surface of the first limiting member 13 facing away from the mounting area 11. The pin body 422 causes at least part of the expansion member 41 to expand and deform in a direction perpendicular to the axis of the expansion hole 411. It can be understood that after the first positioning pin 42 is inserted into the expansion member 41 to cause it to deform, a partial diameter of the expansion member 41 is larger than the diameter of the first limiting hole 131, which can ensure that the first positioning pin 42 will not be separated from the first limiting hole 131, thereby ensuring the stable installation of the terminal board 3 in the mounting groove 141 during operation.

By cooperating with the expansion member 41, the first positioning pin 42 and the mounting groove 141, the terminal board 3 can be confined in the mounting groove 141, thereby realizing the floating assembly of the terminal board 3 in the mounting groove 141, and reducing the influence of vibration during the rotation of the fan 10 on the connection stability between the connector 100 and the terminal board 3.

In some embodiments, please continue to refer to FIG. 4, the wiring holes 32 on the terminal board 3 are arranged linearly and symmetrically distributed on both sides of the second limiting hole 31 along the length direction, so that the wire 2 can extend through the wiring hole 32 and be welded to the terminal board 3, so that the conductive wire and the terminal board 3 are fixed in the same area. It can be understood that after the wire 2 is connected to the wiring hole 32, the wires 2 are distributed on both sides of the second limiting hole 31, that is, the terminal board 3 and the limiting assembly 4 are connected in the center. When the connector 100 is plugged into the terminal board 3, the terminal board 3 is subjected to a more uniform force, which speeds up a docking speed of the connector 100 and the terminal board 3. The arrangement of the wires 2 will not affect a limiting process of the limiting assembly 4 on the terminal board 3, and the arrangement of the wires 2 becomes more reasonable, which increasing the heat dissipation space inside the electronic device.

During actual application, the terminal board 3 is inserted into the mounting grooves 141 along the third direction Z, and the expansion member 41 is embedded in the first limiting hole 131. The first positioning pin 42 is inserted in the second limiting hole 31 and the expansion hole 411, so that the expansion member 41 is deformed in the direction away from the axis of the expansion hole 411, ensuring that the first positioning pin 42 will not be separated from the first limiting hole 131, thereby realizing the floating connection of the terminal board 3 in the mounting grooves 141.

### Second embodiment

A difference of the second embodiment and the first embodiment is that the structure and assembly method of the limiting assembly 4 are different.

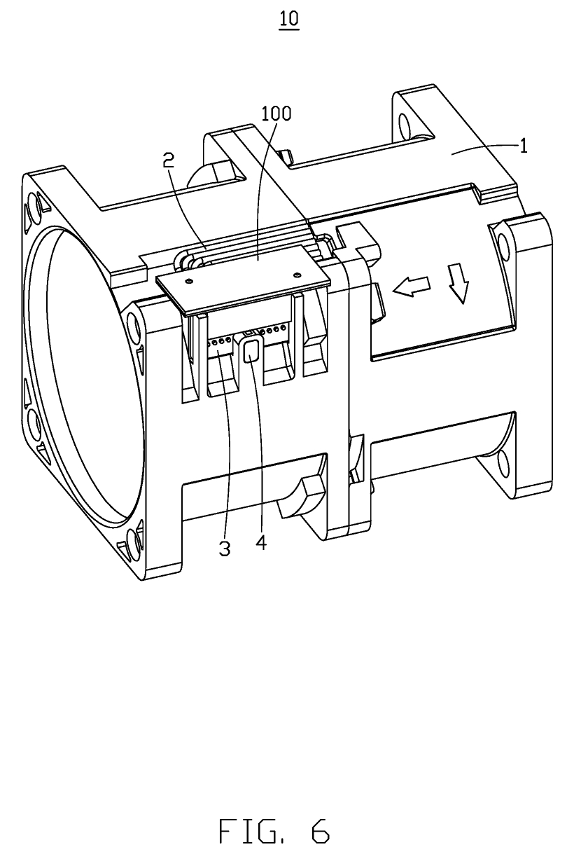

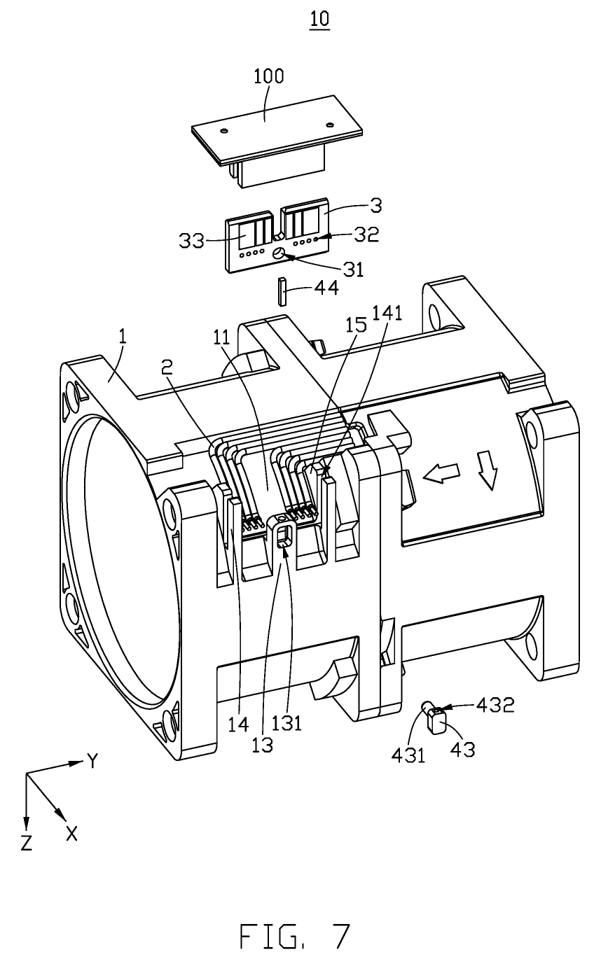

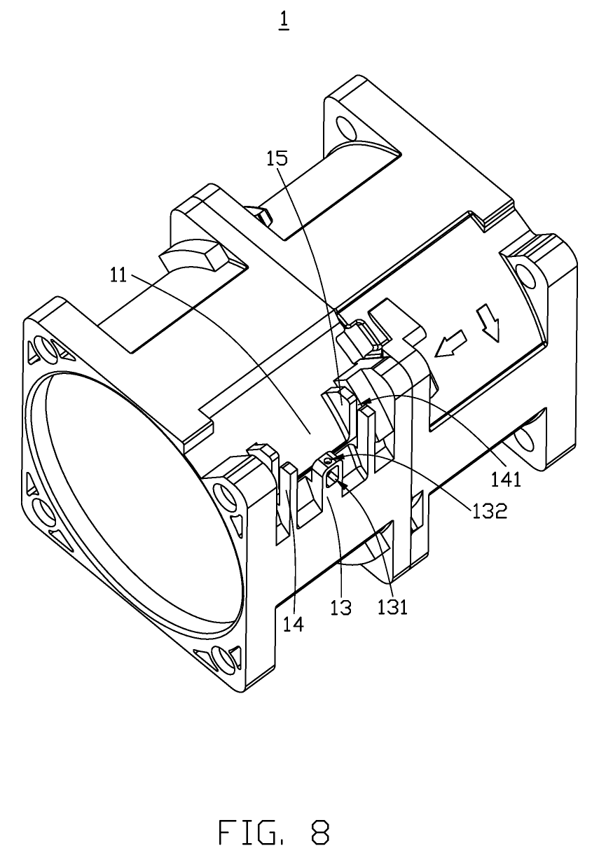

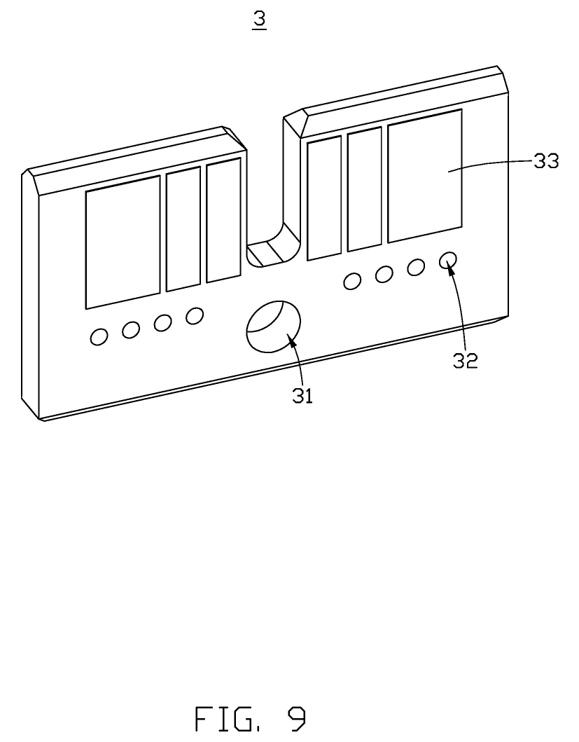

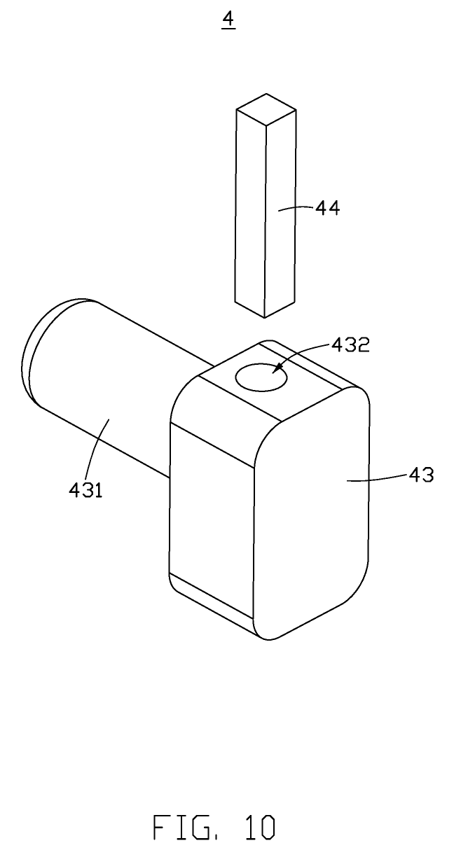

Referring to FIGS. 6 to 10, the limiting assembly 4 includes a positioning body 43 and a second positioning pin 44, at least part of the positioning body 43 is embedded in the first limiting hole 131, and the positioning body 43 does not protrude from a surface of the first limiting member 13 after the positioning body 43 is installed in the first limiting hole 131. It can be understood that the above installation method can improve the aesthetics of the mounting area 11 while reducing the collision of other components with the positioning body 43, thereby ensuring the stable installation of the positioning body 43.

A first positioning column 431 is provided on a surface of the positioning body 43 facing the mounting area 11. The first positioning column 431 is a columnar structure. A diameter of the columnar structure is smaller than the diameters of the first limiting hole 131 and the second limiting hole 31. The first positioning column 431 can connect the first limiting hole 131 and the second limiting hole 31 to ensure that the terminal board 3 will not be separated from the mounting grooves 141 along an installation direction of the first positioning column 431.

The positioning body 43 is provided with a first positioning hole 432 that passes through the positioning body 43 along the third direction Z, and the first limiting member 13 is provided with a second positioning hole 132 at the top of the first limiting member 13 in the third direction Z. An axis of the first positioning hole 432 along the third direction Z coincides with an axis of the second positioning hole 132 along the third direction Z. The cross-sectional shapes of the first positioning hole 432, the second positioning hole 132 and the first positioning column 431 can be circular or other polygonal, which can be selected according to actual needs and are not limited here. The second positioning pin 44 can be installed to the first positioning hole 432 and the second positioning hole 132 along the third direction Z, so that the limiting assembly 4 is fixed to the first limiting hole 131. It can be understood that by fixing the positioning body 43 in the first limiting hole 131 through the second positioning pin 44 , the limiting assembly 4 occupies a smaller system space, which can further increase the heat dissipation space inside the electronic device.

In actual application, the terminal board 3 passes through the mounting grooves 141 along the third direction Z, the positioning body 43 is embedded in the first limiting hole 131, and the first positioning column 431 passes through the first limiting hole 131 and the second limiting hole 31. At the same time, the second positioning pin 44 can be installed to the first positioning hole 432 and the second positioning hole 132 along the third direction Z, so that the positioning body 43 is fixed to the first limiting hole 131, completing the fixing process of the limiting assembly 4. At this time, the terminal board 3 is floatingly installed in the mounting groove 141.

### Third embodiment

The difference between the third embodiment and the first embodiment is that the structure and assembly method of the limiting assembly 4 are different.

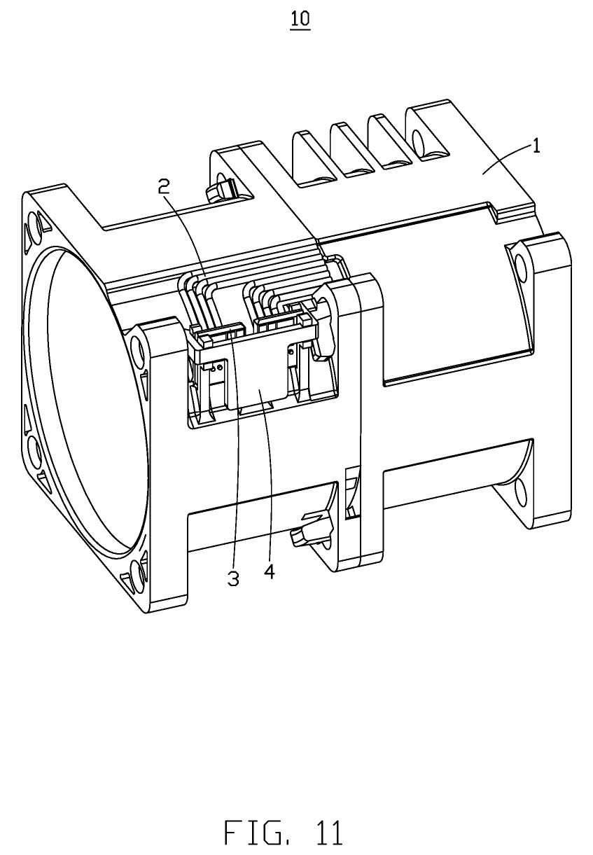

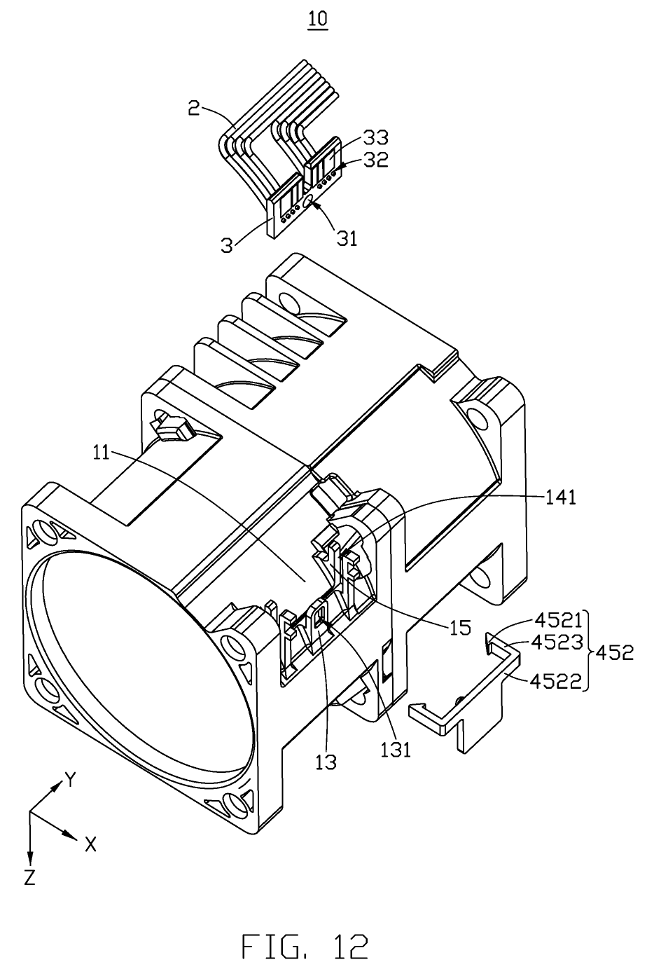

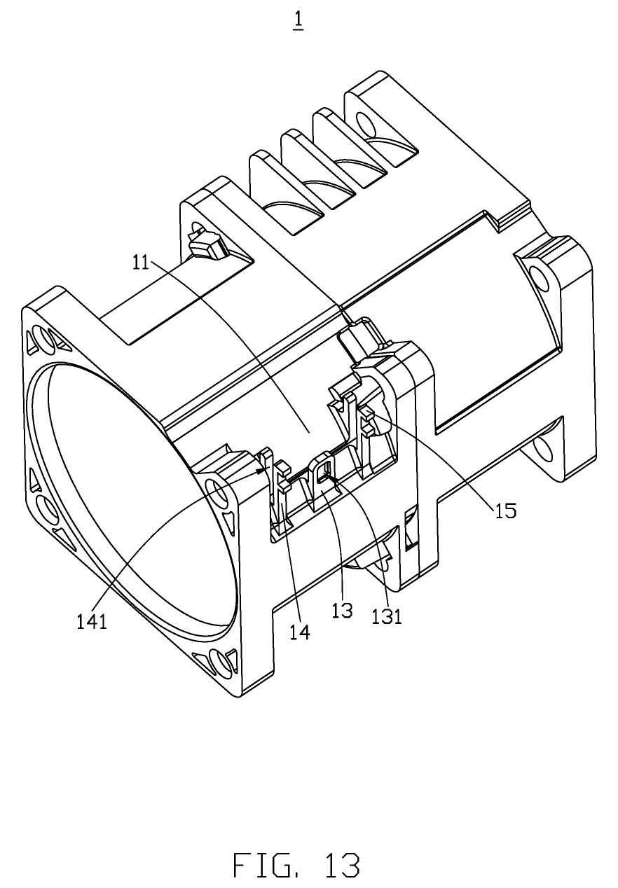

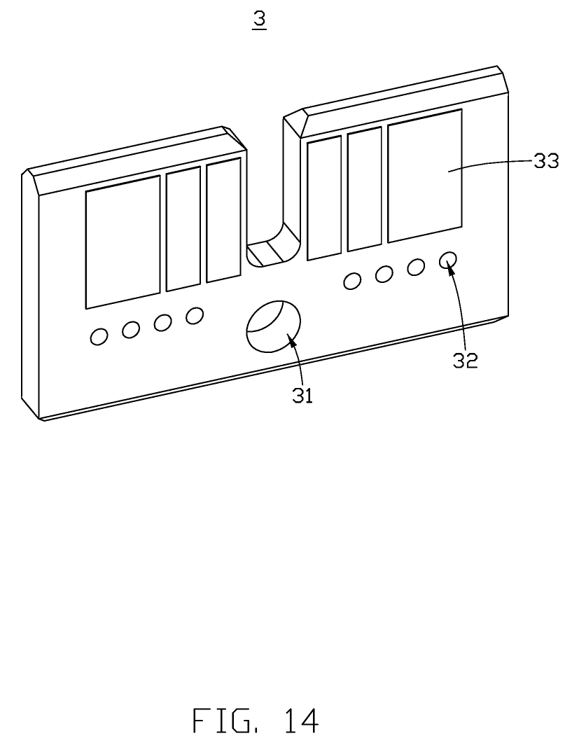

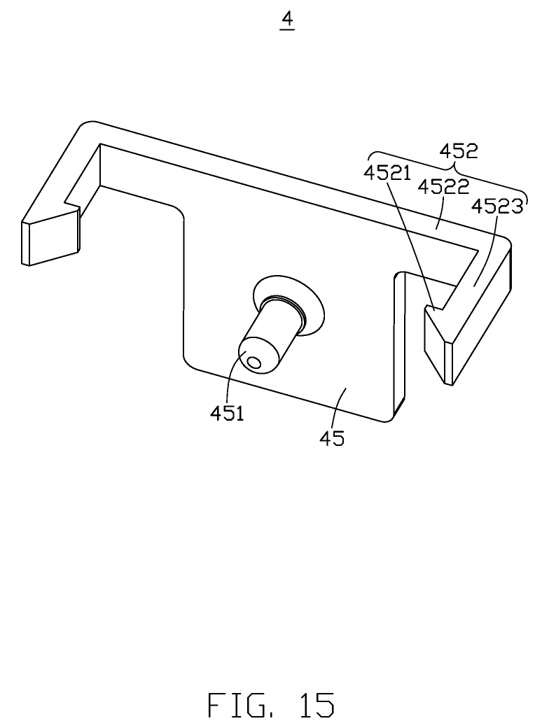

Please refer to FIGS. 11 to 15, the limiting assembly 4 includes a limiting plate 45. The limiting plate 45 is located on a side of the first limiting member 13 facing away from the mounting area 11. A surface of the limiting plate 45 facing the mounting area 11 is provided with a second positioning column 451. The second positioning column 451 is inserted into the first limiting hole 131 and the second limiting hole 31, and a diameter of the second positioning column 451 is smaller than the inner diameters of the first limiting hole 131 and the second limiting hole 31. Through the setting of the second positioning column 451, the limiting plate 45 can be initially clamped in the mounting area 11, and the terminal board 3 can be floatingly connected with the mounting grooves 141.

The limiting assembly 4 also includes two clamping arms 452, which extend from two side wall of the limiting plate 45 toward the first mounting plate 14 and the second mounting plate 15. The clamping arm 452 specifically includes a first extension arm 4522 and a second extension arm 4523 that is connected to and perpendicular to the first extension arm 4522. The second extension arm 4523 extends from one end of the first extension arm 4522 facing away from the limiting plate 45 towards the first mounting plate 14 and the second mounting plate 15. A buckle 4521 is provided at the end of the second extension arm 4523 facing away from the limiting plate 45. It should be noted that a length of the first extension arm 4522 is greater than a spacing distance between the first mounting plate 14 and the second mounting plate 15, and a length of the second extension arm 4523 is greater than a width of the first mounting plate 14 and a width of the second mounting plate 15 along the first direction X, so that after the limiting plate 45 is installed, the buckle 4521 can be clamped with the side of the first mounting plate 14 or the second mounting plate 15 facing away from the limiting plate 45.

It should be noted that the present disclosure does not limit the specific structure of the buckle 4521, which may be a triangular buckle or a rectangular buckle, etc., as long as the clamping arm 452 can be stably connected to the first mounting plate 14 and the second mounting plate 15. The specific structure of the buckle 4521 can be selected according to actual needs.

Furthermore, the first mounting plate 14 and the second mounting plate 15 are provided with clamping grooves 142 on sides of the first mounting plate 14 and the second mounting plate 15 close to the first limiting member 13, and the clamping grooves 142 can be used to receive at least part of the first extension arm 4522. It can be understood that at least part of the first extension arm 4522 is received in the clamping grooves 142, which can reduce a distance between the limiting member plate 45 and the terminal board 3 after the limiting assembly 4 is installed, thereby reducing the system space occupied by the limiting assembly 4 in the first direction X.

After the second positioning column 451 connects the first limiting hole 131 and the second limiting hole 31, it can limit the terminal board 3 from being separated from the limiting grooves. The buckles 4521 of the clamping arms 452 are clamped with the first mounting plate 14 and the second mounting plate 15 to prevent the limiting protrusion from being separated from the first limiting hole 131, thereby ensuring the stable installation of the terminal groove.

During actual application, the terminal board 3 is inserted into the mounting grooves 141 along the third direction Z, the second positioning column 451 of the limiting plate 45 connects the first limiting hole 131 and the second limiting hole 31, and the buckles 4521 can be clamped with sides of the first mounting plate 14 and the second mounting plate 15 facing away from the limiting plate 45, and the first extension arm 4522 is accommodated in the clamping groove 142, so that the limiting plate 45 is stably installed in the mounting area 11, thereby limiting the terminal board 3. At this time, the terminal board 3 is floatingly installed in the mounting groove 141.

It should be noted that a diameter of a portion of the limiting assembly 4 being in contact with the second limiting hole 31 of the terminal board 3 is smaller than the inner diameter of the second limiting hole 31, so that the floating of the terminal board 3 in the first direction X, the second direction Y and the third direction Z are not affected. The present disclosure does not limit the diameter difference, and the diameter difference can be selected according to the specific application scenarios and specifications of the fan 10.

It should also be noted that a shape of the terminal board 3 matches a shape of the connector 100, and the type of the connector 100 can be selected according to actual needs, which is not limited here.

### Fourth embodiment

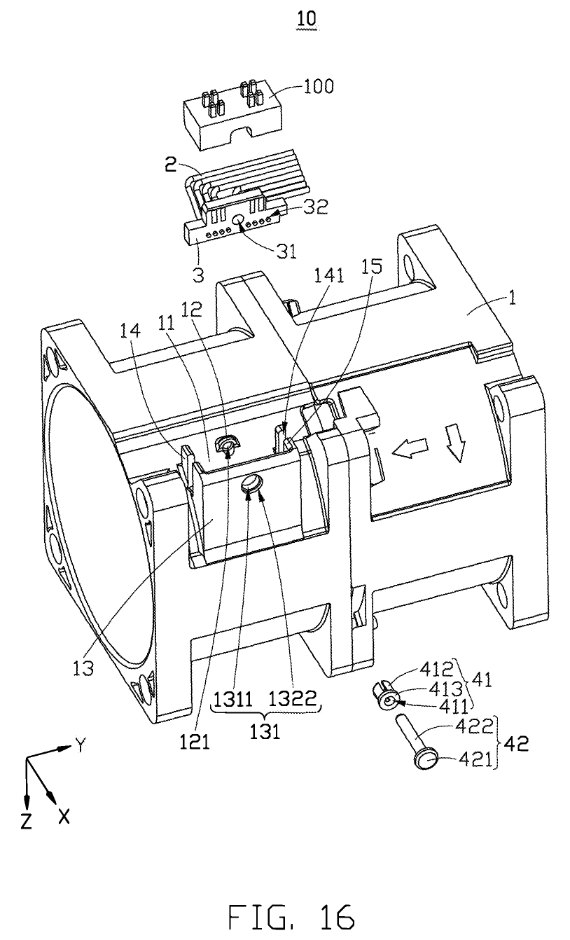

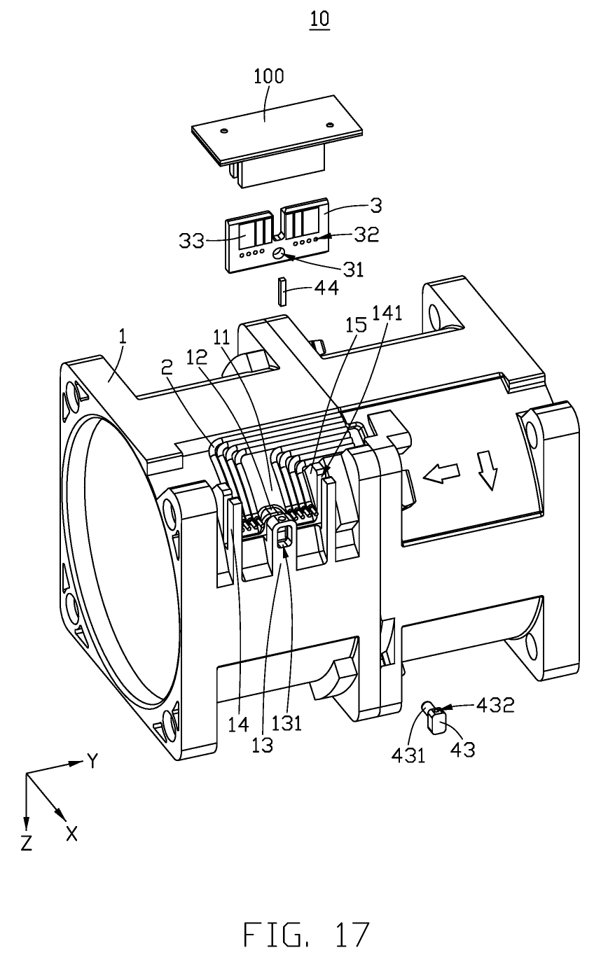

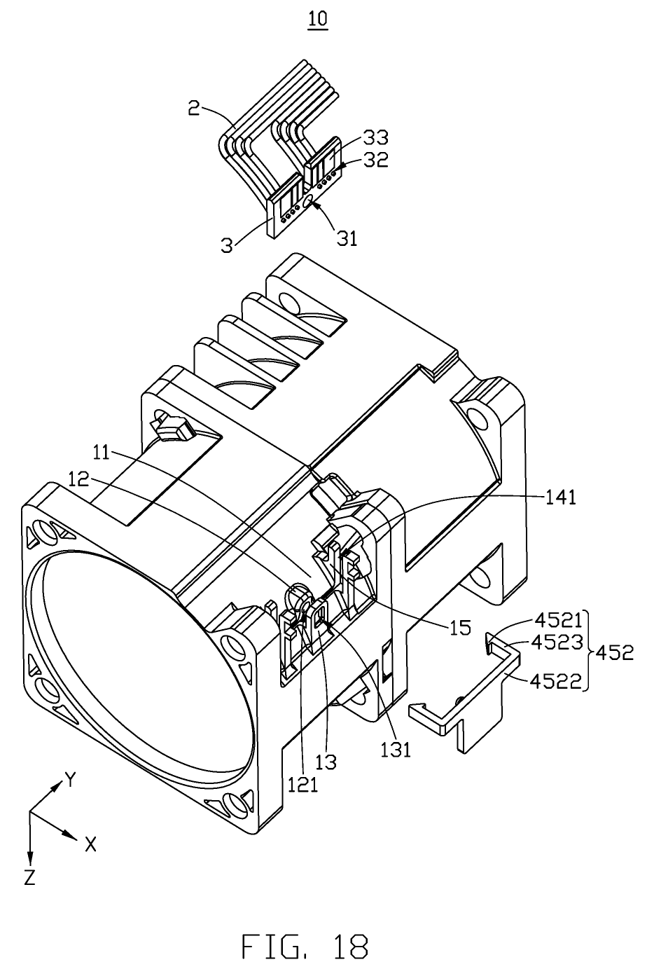

Please refer to FIGS. 16, 17 and 18, the different between the fourth embodiment and the first, second, and third embodiments is that the mounting area 11 is further provided with a second limiting member 12, and the first limiting member 13, the second limiting member 12, the first mounting plate 14, the second mounting plate 15 and the mounting area 11 are an integrally formed structure.

The second limiting member 12 and the first limiting member 13 are arranged opposite to each other along the first direction X, and the second limiting member 12 is provided with a third limiting hole 121 penetrating the second limiting member 12 along the first direction X. When viewed along the first direction X, the first mounting plate 14 and the second mounting plate 15 are located on both sides of the second limiting member 12 and the first limiting member 13. It can be understood that axes of the third limiting hole 121 and the first limiting hole 131 along the first direction X coincide with each other, and the mounting grooves 141 provided on the first mounting plate 14 and the second mounting plate 15 are located on the same straight line along the second direction Y, that is, the axes of the third limiting hole 121 and the first limiting hole 131 along the first direction X are perpendicular to the through direction of the mounting groove 141.

The terminal board 3 movably inserted in the mounting groove 141 is located between the second limiting member 12 and the second limiting portion 413 in the first direction X, and the terminal board 3 is provided with the second limiting hole 31 which passes through the terminal board 3 along the thickness direction. When the terminal board 3 is installed to the mounting groove 141, axes of the second limiting hole 31, the third limiting hole 121 of the second limiting member 12 and the first limiting hole 131 of the first limiting member 13 along the first direction X coincide with each other. By connecting the third limiting hole 121, the first limiting hole 131 and the second limiting hole 31 through the limiting assembly 4, the terminal board 3 can be floatingly connected to the mounting groove 141.

### Fifth embodiment

The difference between the fifth embodiment and the first embodiment, the second embodiment, the third embodiment and the fourth embodiment is that the fan further includes a shock absorbing member 5.

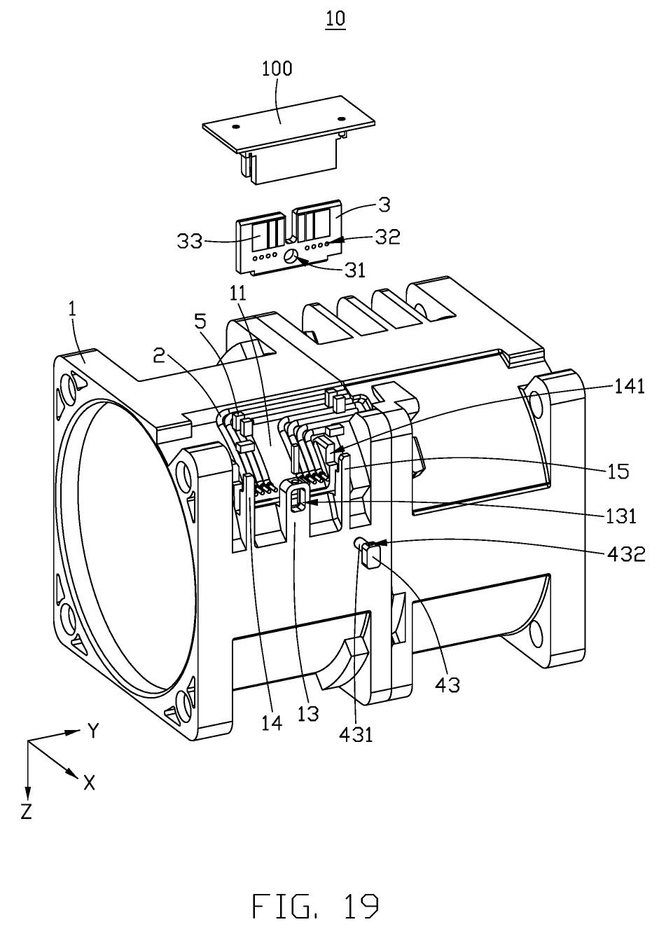

Referring to FIG. 19, taking the structure of the fan 10 of the second embodiment as an example, the shock absorbing member 5 is arranged in the mounting groove 141, and is located between a surface of the terminal board 3 and walls (side wall and bottom wall) of the mounting groove 141. It can be understood that a certain vibration will be generated during the operation of the fan, and this vibration is transmitted to the terminal board 3 through the abutment between the mounting groove 141 and the terminal board 3, which has a certain impact on the connection stability between the terminal board 3 and the connector 100. By arranging the shock absorbing member 5 between the surface of the terminal board 3 and the walls of the mounting groove 141, the impact of the fan vibration on the connection stability between the terminal board 3 and the connector 100 can be further reduced.

It can be understood that, in addition to the structure shown in the second embodiment, the arrangement of the shock absorbing member 5 in the mounting groove 141 can also be applied to the first, second, and third embodiments.

As an optional technical solution of the present disclosure, different from the embodiments 1 to 5, the limiting assembly 4 may not be provided, and a structural component for opening or closing an entrance of the mounting groove 141 may be provided at the entrance of the mounting groove 141 of the first mounting plate 14 and the second mounting plate 15. The structural component includes, but is not limited to, a baffle, a matching structure of a pin and a hole installed along the first direction, or an elastic clip, etc., which can open or close the mounting groove 141. It can be understood that after the terminal board 3 is installed to the mounting groove 141 along the third direction, the entrance of the mounting groove 141 is closed by the structural component, which can limit the terminal board 3 from detaching from the entrance, thereby realizing floating connection between the terminal board 3 and the mounting groove 141.

As an optional technical solution of the present disclosure, different from the embodiments 1 to 5, the limiting assembly 4 and the mounting groove 141 may not be provided, and mounting holes penetrating along the second direction may be provided on the first mounting plate 14 and the second mounting plate 15, mounting rods are provided at both ends of the terminal board 3, the inner diameter of the mounting hole is larger than the diameter of the mounting rod, and the side walls of the first mounting plate 14 and the second mounting plate 15 are provided with mounting channels connected to the mounting holes, and the mounting channels include at least one bending portion. It can be understood that the terminal board 3 can enter the mounting hole along the mounting channel through the mounting rod, so that the mounting rod can move in the mounting hole along the first direction and the second direction. Due to the bending path setting of the mounting channel, the terminal board 3 will not be separated from the mounting hole.

As an optional technical solution of the present disclosure, different from the embodiments of 1 to 5, the limiting assembly 4 and the mounting groove 141 may not be provided, and first mounting holes extending along the second direction is provided on the first mounting plate 14 and the second mounting plate 15, and second mounting holes are provided on both sides of the terminal board 3 in the second direction. The fan 10 further includes a mounting pin, and a portion of the mounting pin has a diameter smaller than a diameter of the mounting hole. It can be understood that the terminal board 3 can be installed in the mounting area 11, and the mounting pin passes through the first mounting hole and is connected to the second mounting hole of the terminal board. At this time, the mounting pin can move in the first mounting hole, thereby realizing the floating assembly of the terminal board 3 in the mounting area.

It should be noted that the shapes of the first limiting hole 131, the second limiting hole 31, the third limiting hole 121, the first positioning hole 432, the second positioning hole 132 and the wiring hole 32 provided in the present disclosure include, but are not limited to, round holes or other polygonal holes, which can be selected according to actual needs and are not limited here.

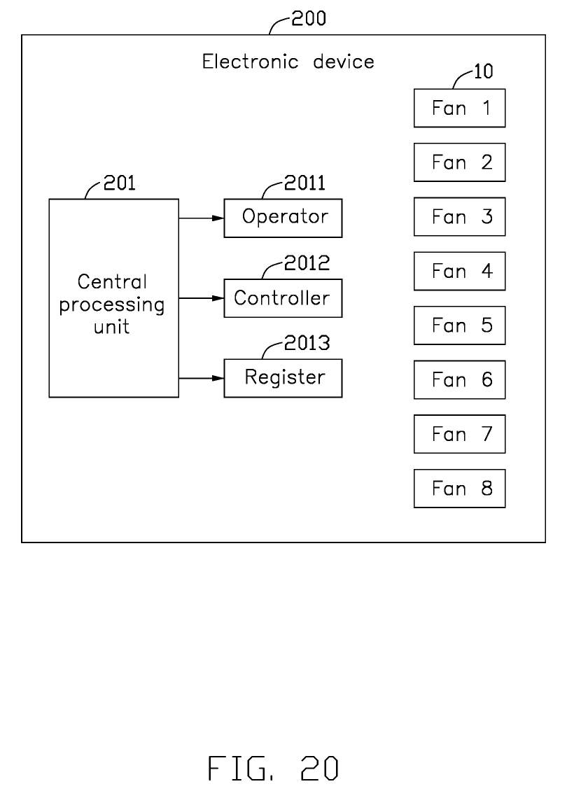

The present disclosure also provides an electronic device 200. The electronic device 200 includes, but is not limited to, a server, a switch or a router. Referring to FIG. 20, taking a central processing unit 201 of the server as an example, the main components inside the central processing unit 201 include an operator 2011, a controller 2012 and a register 2013. The operator 2011 is used for arithmetic and logical operations. The controller 2012 is configured to direct and coordinate the work of other components to ensure that all parts of the computer run in an orderly manner. The register 2013 is configured to temporarily store instructions, data and addresses, so that the central processing unit 201 can quickly obtain information and improve processing efficiency. The operation process of the operator 2011, the controller 2012 and the register 2013 and other components will generate heat, and the fan 10 can promote air flow to take away the heat on the radiator, thereby ensuring that the central processing unit 201 works at a suitable temperature, and preventing the central processing unit 201 from degrading or being damaged due to overheating.

In addition to the above embodiments, the fan 10 can be applied to other electronic devices 200, and the number of fans 10 is not limited to eight. Eight is only an example. A larger number of fans 10 can be used, such as ten or twelve, etc., or a smaller number of fans 10 can be used, such as one, two or four, etc. The type of electronic device 200 and the number of fans 10 can be selected according to actual needs and are not limited here.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A fan comprising:
a frame, the frame comprising a mounting area;
a first limiting member, a first mounting plate, and a second mounting plate provided in the mounting area, wherein the first mounting plate and the second mounting plate are located on opposite sides of the first limiting member in a second direction, the first limiting member comprising a first limiting hole penetrating the first limiting member along a first direction perpendicular to the second direction, the first mounting plate comprising a mounting groove penetrating the first mounting plate along the second direction, and the second mounting plate comprising a mounting groove penetrating the second mounting plate along the second direction;
a plurality of wires, first ends of the plurality of wires extending into the frame, and second ends of the plurality of wires opposite to the first end extending outside the frame;
a terminal board movably inserted into the mounting grooves of the first mounting plate and the second mounting plate, and comprising a second limiting hole and a plurality of wiring holes penetrating the terminal board along a thickness direction of the terminal board, wherein an axis of the first limiting hole along the first direction coincides with an axis of the second limiting hole, and the plurality of wiring holes is configured to connect the second ends of the plurality of wires; and
a limiting assembly configured to connect the first limiting hole and the second limiting hole, wherein a diameter of the second limiting hole is greater than a diameter of at least part of the limiting assembly such that the terminal board is floatingly connected to the mounting grooves.

2. The fan of claim 1, wherein the limiting assembly comprises:
an expansion member received in the first limiting hole, the expansion member is provided with an expansion hole, an axis of the expansion hole coincides with the axis of the second limiting hole; and
a first positioning pin comprising a first limiting portion ad a pin body, wherein the first limiting portion abuts against a surface of the first limiting member facing away from the mounting area, the pin body extends through the expansion hole and the first limiting hole, and at least part of the expansion member is configured to expand and deform in a direction perpendicular to the axis of the expansion hole.

3. The fan of claim 2, wherein the first limiting hole comprises a first hole section and a second hole section, the second hole section is arranged at one end of the first hole section away from the mounting area, and a diameter of the second hole section is greater than a diameter of the first hole section;
the expansion member comprises an expansion body and a second limiting portion, a diameter of the second limiting portion is greater than the diameter of the first hole section, the expansion body is received in the first hole section, the second limiting member is received in the second hole section, , and the second limiting member does not protrude from a surface of the first limiting member.

4. The fan of claim 1, wherein the limiting assembly comprises:
a positioning body, at least part of the positioning body is embedded in the first limiting hole, the positioning body is provided with a first positioning column, the first positioning column is configured to connect the first limiting hole and the second limiting hole; the positioning body comprises a first positioning hole, the first limiting member comprises a second limiting hole at a top of the first limiting member in a third direction perpendicular to the first direction and the second direction, an axis of the first positioning hole along the third direction coincides with an axis of the second positioning hole along the third direction; and
a second positioning pin configured to connect the first positioning hole and the second positioning hole.

5. The fan of claim 1, wherein the limiting assembly comprises:
a limiting plate on a side of the first limiting member facing away from the mounting area, the limiting plate is provided with a positioning column; and
two clamping arms extending from two side walls of the limiting plate towards the mounting area, two ends of the two clamping arms facing away from the limiting plate are respectively provided with two buckles, the limiting plate is configured to connect the first limiting hole and the second limiting hole through the positioning column, and the two buckles are clamped with the first mounting plate and the second mounting plate.

6. The fan of claim 5, wherein each of the two clamping arms comprises a first extension arm and a second extension arm connected to each other, the second extension arm extends from an end of the first extension arm facing away from the limiting plate towards the mounting area;
a side of each of the first mounting plate and the second mounting plate close to the first limiting plate comprises a clamping groove, the limiting plate is configured to be mounted on a side of the first limiting member facing away from the mounting area through the positioning column, at least part of the first extension arm is received in the clamping groove.

7. The fan of claim 1, further comprising a second limiting member provided in the mounting area, wherein the second limiting member and the first limiting member are arranged opposite to each other in the first direction, the second limiting member comprises a third limiting hole penetrating the second limiting member along the first direction, axes of the first limiting member, the second limiting member, and the third limiting member along the first direction coincide with each other, and the limiting assembly is configured to connect the first limiting hole, the second limiting hole, and the third limiting hole.

8. The fan of claim 1, further comprising a shock absorbing member disposed in the mounting groove and located between the terminal board and walls of the mounting groove.

9. The fan of claim 1, wherein the terminal board is provided with a plurality of electrical contact areas, the plurality of electrical contact areas is distributed on two surfaces of the terminal board, and at least some of the plurality of electrical contact areas have different areas.

10. An electronic device comprising a fan, the fan comprising:
a frame, the frame comprising a mounting area;
a first limiting member, a first mounting plate, and a second mounting plate provided in the mounting area, wherein the first mounting plate and the second mounting plate are located on opposite sides of the first limiting member in a second direction, the first limiting member comprising a first limiting hole penetrating the first limiting member along a first direction perpendicular to the second direction, the first mounting plate comprising a mounting groove penetrating the first mounting plate along the second direction, and the second mounting plate comprising a mounting groove penetrating the second mounting plate along the second direction;
a plurality of wires, first ends of the plurality of wires extending into the frame, and second ends of the plurality of wires opposite to the first end extending outside the frame;
a terminal board movably inserted into the mounting grooves of the first mounting plate and the second mounting plate, and comprising a second limiting hole and a plurality of wiring holes penetrating the terminal board along a thickness direction of the terminal board, wherein an axis of the first limiting hole along the first direction coincides with an axis of the second limiting hole, and the plurality of wiring holes is configured to connect the second ends of the plurality of wires; and
a limiting assembly configured to connect the first limiting hole and the second limiting hole, wherein a diameter of the second limiting hole is greater than a diameter of at least part of the limiting assembly such that the terminal board is floatingly connected to the mounting grooves.

11. The electronic device of claim 10, wherein the limiting assembly comprises:
an expansion member received in the first limiting hole, the expansion member is provided with an expansion hole, an axis of the expansion hole coincides with the axis of the second limiting hole; and
a first positioning pin comprising a first limiting portion ad a pin body, wherein the first limiting portion abuts against a surface of the first limiting member facing away from the mounting area, the pin body extends through the expansion hole and the first limiting hole, and at least part of the expansion member is configured to expand and deform in a direction perpendicular to the axis of the expansion hole.

12. The electronic device of claim 11, wherein the first limiting hole comprises a first hole section and a second hole section, the second hole section is arranged at one end of the first hole section away from the mounting area, and a diameter of the second hole section is greater than a diameter of the first hole section;
the expansion member comprises an expansion body and a second limiting portion, a diameter of the second limiting portion is greater than the diameter of the first hole section, the expansion body is received in the first hole section, the second limiting member is received in the second hole section, and the second limiting member does not protrude from a surface of the first limiting member.

13. The electronic device of claim 10, wherein the limiting assembly comprises:
a positioning body, at least part of the positioning body is embedded in the first limiting hole, the positioning body is provided with a first positioning column, the first positioning column is configured to connect the first limiting hole and the second limiting hole; the positioning body comprises a first positioning hole, the first limiting member comprises a second limiting hole at a top of the first limiting member in a third direction perpendicular to the first direction and the second direction, an axis of the first positioning hole along the third direction coincides with an axis of the second positioning hole along the third direction; and
a second positioning pin configured to connect the first positioning hole and the second positioning hole.

14. The electronic device of claim 10, wherein the limiting assembly comprises:
a limiting plate on a side of the first limiting member facing away from the mounting area, the limiting plate is provided with a positioning column; and
two clamping arms extending from two side walls of the limiting plate towards the mounting area, two ends of the two clamping arms facing away from the limiting plate are respectively provided with two buckles, the limiting plate is configured to connect the first limiting hole and the second limiting hole through the positioning column, and the two buckles are clamped with the first mounting plate and the second mounting plate.

15. The electronic device of claim 14, wherein each of the two clamping arms comprises a first extension arm and a second extension arm connected to each other, the second extension arm extends from an end of the first extension arm facing away from the limiting plate towards the mounting area;
a side of each of the first mounting plate and the second mounting plate close to the first limiting plate comprises a clamping groove, the limiting plate is configured to be mounted on a side of the first limiting member facing away from the mounting area through the positioning column, at least part of the first extension arm is received in the clamping groove.

16. The electronic device of claim 10, further comprising a second limiting member provided in the mounting area, wherein the second limiting member and the first limiting member are arranged opposite to each other in the first direction, the second limiting member comprises a third limiting hole penetrating the second limiting member along the first direction, axes of the first limiting member, the second limiting member, and the third limiting member along the first direction coincide with each other, and the limiting assembly is configured to connect the first limiting hole, the second limiting hole, and the third limiting hole.

17. The electronic device of claim 10, further comprising a shock absorbing member disposed in the mounting groove and located between the terminal board and walls of the mounting groove.

18. The electronic device of claim 10, wherein the terminal board is provided with a plurality of electrical contact areas, the plurality of electrical contact areas is distributed on two surfaces of the terminal board, and at least some of the plurality of electrical contact areas have different areas.
